(19) United States
(12) Patent Application Publication
(10) Pub. No.: US 2015/0207025 A1
(43) Pub. Date: Jul. 23, 2015

(54) METHOD OF MANUFACTURING SEMICONDUCTOR LIGHT EMITTING DEVICE AND METHOD OF MANUFACTURING SEMICONDUCTOR LIGHT EMITTING DEVICE PACKAGE

(71) Applicants: Do Young RHEE, Seoul (KR); Sung Tae KIM, Seoul (KR); Young Sun KIM, Suwon-si (KR); Chul Min KIM, Gunpo-si (KR); Suk Ho YOON, Seoul (KR); Sang Don LEE, Suwon-si (KR)

(72) Inventors: Do Young RHEE, Seoul (KR); Sung Tae KIM, Seoul (KR); Young Sun KIM, Suwon-si (KR); Chul Min KIM, Gunpo-si (KR); Suk Ho YOON, Seoul (KR); Sang Don LEE, Suwon-si (KR)

(21) Appl. No.: 14/472,159

(22) Filed: Aug. 28, 2014

(30) Foreign Application Priority Data
Jan. 20, 2014 (KR) 10-2014-0006522

(51) Int. Cl. H01L 33/00; H01L 33/12

(52) U.S. Cl. CPC H01L 33/0075; H01L 33/12

(57) ABSTRACT

A method of manufacturing a semiconductor light emitting device includes forming, on a substrate, a first region of a light emitting structure and the light emitting structure includes a first conductivity-type semiconductor layer, an active layer, and a second conductivity-type semiconductor layer. A protective layer is formed on the first region in a first chamber. The substrate with the first region and the protective layer formed thereon is transferred to a second chamber. A second region is formed on the first region. The first and second regions are disposed in a direction perpendicular to the substrate. The protective layer is grown above a defective region included in the first region and removed before or while the second region is formed.

### CROSS-REFERENCE TO RELATED APPLICATION

This application claims benefit of priority to Korean Patent Application No. 10-2014-0006522 filed on Jan. 20, 2014, with the Korean Intellectual Property Office, the entire content of which is incorporated herein by reference.

### TECHNICAL FIELD

The present disclosure relates to a method of manufacturing a semiconductor light emitting device and a method of manufacturing a semiconductor light emitting device package.

### BACKGROUND

Light emitting diodes (LEDs) having advantages such as long lifespans, low power consumption, a fast response speeds, environmental friendliness, and the like, as compared to related art light sources, have been seen as being next generation light sources, and have come to prominence as being important light sources in various products such as lighting devices and the backlights of display devices. In particular, LEDs based on Group III nitrides such as GaN, AlGaN, InGaN, InAlGaN, and the like, serve as semiconductor light emitting devices outputting blue or ultraviolet light.

A nitride semiconductor single crystal constituting a light emitting device using a Group III nitride semiconductor is grown on a substrate such as a sapphire, silicon (Si), or SiC substrate, and in general, in order to grow a nitride semiconductor single crystal, chemical vapor deposition (CVD) using a gaseous source is used. Light emitting performance and reliability of semiconductor light emitting devices are dependent upon the quality of semiconductor layers constituting the semiconductor light emitting device, and the quality of semiconductor layers may be affected by a structure, an internal environment, usage conditions, and the like, of a CVD apparatus used to grow semiconductor thin films.

### SUMMARY

An aspect of the present disclosure may provide a method of manufacturing a semiconductor light emitting device and a method of manufacturing a semiconductor light emitting device package capable of enhancing luminous efficiency and productivity.

One aspect of the present disclosure relates to a method of manufacturing a semiconductor light emitting device including forming, on a substrate, a first region of a light emitting structure, the light emitting device including a first conductivity-type semiconductor layer, an active layer, and a second conductivity-type semiconductor layer. A protective layer is formed on the first region in a first chamber. The substrate with the first region and the protective layer formed thereon is transferred to a second chamber. A second region is formed on the first region. The first and second regions are disposed in a direction perpendicular to the substrate. The protective layer is grown above a defective region included in the first region and removed before or while the second region is formed.

The protective layer may be formed to have a first thickness on the defective region and to have a second thickness lower than the first thickness on a region other than the defective region.

The protective layer may have a protrusion protruding from the defective region.

The defective region may be a region in which a threading dislocation is formed.

The first region may have a pit formed in an upper surface of the defective region.

The protective region may be disposed within the pit.

The protective layer may include a plurality of island regions disposed above the defective region.

The protective layer may have a composition of AlₓIn_{y}Ga_{1-x-y}N (0≦x<1, 0<y≦1).

The protective layer may be formed of InN.

The protective layer may be formed of a material having volatility at a temperature of approximately 700° C. or higher.

The protective layer may be formed at a temperature ranging from approximately 450° C. to 800° C.

The second region may be formed at a temperature above a temperature at which a material constituting the protective layer is decomposed to be volatilized.

The forming of the second region may include injecting a hydrogen (H₂) gas.

During the transfer of the substrate, the substrate with the first region and the protective layer formed thereon may be exposed in the air.

The first region may include the first conductivity-type semiconductor layer and the active layer, and the second region may include the second conductivity-type semiconductor layer.

In the forming of the first region, the first conductivity-type semiconductor layer may be formed on the substrate within the first chamber, and the active layer and the protective layer may be formed on the first conductivity-type semiconductor layer within the second chamber. In the forming of the second region, the second conductivity-type semiconductor layer may be formed on the active layer within a third chamber.

The first region may include the first conductivity-type semiconductor layer, and the second region may include the active layer and the second conductivity-type semiconductor layer.

The first region may include a lower layer of the first conductivity-type semiconductor layer, and the second region may include an upper layer of the first conductivity-type semiconductor layer, the active layer, and the second conductivity-type semiconductor layer.

The first conductivity-type semiconductor layer, the active layer, and the second conductivity-type semiconductor layer may be formed within respective chambers that are different from one another.

The forming of the first region, the forming of the protective layer, and the forming of the second region may be repeatedly performed twice, respectively, and the protective layer may be formed on upper surfaces of the first conductivity-type semiconductor layer and the active layer.

Another aspect of the present disclosure encompasses a method of manufacturing a semiconductor light emitting device including forming, on a substrate. A part of a light emitting structure as a first region is formed. The light emitting structure includes a plurality of semiconductor layers and the first region includes a defective region. A protective layer covering an upper portion of the defective region is formed on the first region. At least a part of the remaining region of the light emitting structure as a second region is formed on the first region.

The protective layer may be formed to have a first thickness on the defective region and to have a second thickness lower than the first thickness on a region other than the defective region.

The protective layer may be formed only on the defective region.

Still another aspect of the present disclosure relates to a method of manufacturing a semiconductor light emitting device package including growing a first conductivity-type semiconductor layer, an active layer, and a second conductivity-type semiconductor layer on a substrate to form a light emitting structure. At least a portion of the light emitting structure is removed to form a first electrode electrically connected to the first conductivity-type semiconductor layer. A second electrode electrically connected to the second conductivity-type semiconductor layer is formed. The light emitting structure is mounted on a package board. In the forming of the light emitting structure, a part of a light emitting structure including a plurality of semiconductor layers and including a defective region is formed as a first region. A protective layer covering an upper portion of the defective region is formed on the first region. At least a part of the remaining region of the light emitting structure is formed as a second region on the first region.

Still another aspect of the present disclosure encompasses a method of manufacturing a semiconductor light emitting device, including forming, on a substrate, a first portion of a light emitting structure, the first portion including a defective region. A protective layer is formed on the defective region in a first chamber. The protective layer is removed in a second chamber. The remaining portion of the light emitting structure is formed.

The light emitting structure may include a first conductivity-type semiconductor layer, an active layer, and a second conductivity-type semiconductor layer.

The removing of the protective layer may be performed before the forming of the remaining of the light emitting structure.

The removing of the protective layer may be performed while performing the forming of the remaining of the light emitting structure.

The duration of the removing of the protective layer partially may overlap with the duration of performing the forming of the remaining of the light emitting structure.

The method may include transferring the substrate with the first portion and the protective layer formed thereon from the first chamber to the second chamber.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a cross-sectional view schematically illustrating a semiconductor light emitting device according to an example embodiment of the present inventive concept.

FIG. 2 is a flow chart illustrating a method of manufacturing a semiconductor light emitting device according to an example embodiment of the present inventive concept.

FIGS. 3A through 3F are cross-sectional views schematically illustrating a method of manufacturing a semiconductor light emitting device according to an example embodiment of the present inventive concept.

FIGS. 4A and 4B are cross-sectional views illustrating a process of the method of manufacturing a semiconductor light emitting device according to an example embodiment of the present inventive concept.

FIGS. 5A and 5B are cross-sectional views illustrating a process of the method of manufacturing a semiconductor light emitting device according to an example embodiment of the present inventive concept.

FIG. 6 is a graph illustrating characteristics of a semiconductor light emitting device according to an example embodiment of the present inventive concept.

FIGS. 7A through 7C are cross-sectional views schematically illustrating a method of manufacturing a semiconductor light emitting device according to an example embodiment of the present inventive concept.

FIGS. 8A through 8C are cross-sectional views schematically illustrating a method of manufacturing a semiconductor light emitting device according to an example embodiment of the present inventive concept.

FIGS. 9 and 10 are views illustrating examples of packages employing a semiconductor light emitting device according to an example embodiment of the present inventive concept.

FIGS. 11 and 12 are views illustrating examples of backlights employing a semiconductor light emitting device according to an example embodiment of the present inventive concept.

FIG. 13 is a view illustrating an example of a lighting device employing a semiconductor light emitting device according to an example embodiment of the present inventive concept.

FIG. 14 is a view illustrating an example of a headlamp employing a semiconductor light emitting device according to an example embodiment of the present inventive concept.

### DETAILED DESCRIPTION

Hereinafter, example embodiments of the present inventive concept will be described in detail with reference to the accompanying drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

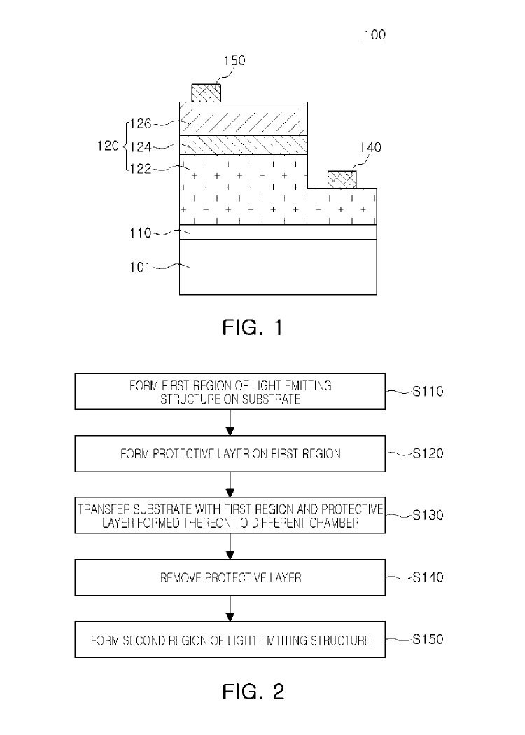

FIG. 1 is a cross-sectional view schematically illustrating a semiconductor light emitting device according to an example embodiment of the present inventive concept.

Referring to FIG. 1, a semiconductor light emitting device 100 may include a substrate 101, a buffer layer 110 disposed on the substrate 101, and a light emitting structure 120. The light emitting structure 120 may include a first conductivity-type semiconductor layer 122, an active layer 124, and a second conductivity-type semiconductor layer 126. Also, the semiconductor light emitting device 100 may include first and second electrodes 140 and 150 as electrode structures.

In the present disclosure, unless otherwise mentioned, terms such as ‘upper portion’, ‘upper surface’, ‘lower portion’, ‘lower surface’, ‘lateral surface’, and the like, are determined based on the drawings, and in actuality, the terms may be changed according to a direction in which a device is actually disposed.

The substrate 101 may be provided as a semiconductor growth substrate and may be formed of an insulating, a conductive, or a semiconductive material such as sapphire, SiC, MgAl₂O₄, MgO, LiAlO₂, LiGaO₂, GaN, or the like. A sapphire substrate is a crystal having Hexa-Rhombo R3c symmetry, of which lattice constants in c-axial and a-axial directions are approximately 13.001 Å and 4.758 Å, respectively, and has a C-plane (0001), an A-plane (11−20), an R-plane (1−102), and the like. In this case, the C-plane of sapphire crystal allows a nitride thin film to be relatively easily grown thereon and is stable at high temperatures, so the sapphire substrate is commonly used as a nitride growth substrate. Meanwhile, when the substrate 101 is formed of silicon (Si), it may be more appropriate for increasing a diameter and is relatively low in price, facilitating mass-production. Meanwhile, although not shown, a depression and protrusion pattern may be formed on an upper surface of the substrate 101, namely, on a growth surface of the semiconductor layers, and crystallinity, luminous efficiency, and the like, of the semiconductor layers may be enhanced by the depression and protrusion pattern.

Also, according to an example embodiment of the present inventive concept, the substrate 101 may also serve as an electrode of the semiconductor light emitting device 100 together with the first electrode 140 or replacing the first electrode 140, and in this case, the substrate 101 may be formed of a conductive material. Thus, the substrate 101 may be formed of a material including any one of gold (Au), nickel (Ni), aluminum (Al), copper (Cu), tungsten (W), silicon (Si), selenium (Se), germanium (Ge), a gallium nitride (GaN), and a gallium arsenide (GaAs), for example, a material obtained by doping aluminum in silicon (Si).

The buffer layer 110 may alleviate a lattice defect of the light emitting structure 120 grown on the substrate 101. For example, the buffer layer 110 may be formed as an undoped semiconductor layer formed of a nitride such as AlN, GaN, InGaN, or AlGaN. Here, the “undoped semiconductor layer” refers to a semiconductor layer which has not been undergone an impurity doping process. The semiconductor layer may have an inherent level of impurity concentration. For example, the buffer layer 110 may alleviate a difference in lattice constants between the substrate 101 formed of sapphire and the first conductivity-type semiconductor layer 122 formed of GaN to increase crystallinity of the GaN layer. However, the buffer layer 110 is not essential and may be omitted according to an example embodiment of the present inventive concept.

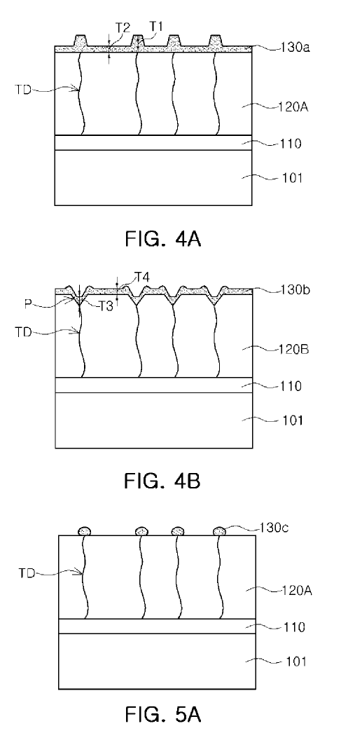

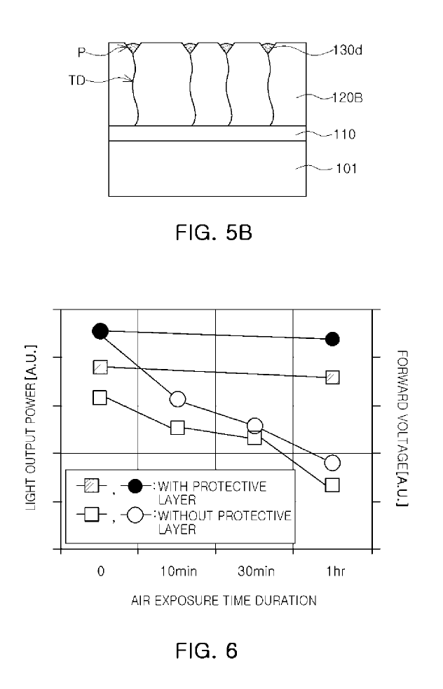

The light emitting structure 120 may include the first conductivity-type semiconductor layer 122, the active layer 124, and the second conductivity-type semiconductor layer 126. At least one of the semiconductor layers constituting the light emitting structure 120 may include a defective region including a defect such as dislocation. The dislocation may be, for example, a threading dislocation, and may be formed due to a difference in lattice constants between the substrate 101 and the semiconductor layers constituting the light emitting structure 120. The threading dislocation may be formed in a direction perpendicular to the substrate 101, and may extend within the semiconductor layers constituting the light emitting structure 120. This will be described in detail with reference to FIGS. 4A through 5B hereinafter.

The first and second conductivity-type semiconductor layers 122 and 126 may respectively be formed of semiconductor doped with an n-type impurity and a p-type impurity, but the present disclosure is not limited thereto and, conversely, the first and second conductivity-type semiconductor layers 122 and 126 may respectively be formed of p-type and n-type semiconductor. The first and second conductivity-type semiconductor layers 122 and 126 may be formed of a nitride semiconductor, e.g., a material having a composition of AlₓIn_{y}Ga_{1-x-y}N (0≦x≦1, 0≦y≦1, 0≦x+y≦1). Each of the semiconductor layers 122 and 126 may be configured as a single layer, or may include a plurality of layers having different characteristics such as different doping concentrations, compositions, and the like. Here, the first and second conductivity-type semiconductor layers 122 and 126 may be formed of an AlInGaP or AlInGaAs semiconductor, besides a nitride semiconductor.

The active layer 124, disposed between the first and second conductivity-type semiconductor layers 122 and 126, emits light having a certain level of energy according to the recombination of electrons and holes and may have a multi-quantum well (MQW) structure in which quantum well layers and quantum barrier layers are alternately laminated. For example, in the case of the nitride semiconductor, a GaN/InGaN structure may be used. A single quantum well (SQW) structure may also be used as needed.

The first and second electrodes 140 and 150 may be electrically connected to the first and second conductivity-type semiconductor layers 122 and 126, respectively. The first and second electrodes 140 and 150 may be formed by depositing an electrically conductive material, for example, one or more of silver (Ag), aluminum (Al), nickel (Ni), and chromium (Cr). According to an example embodiment of the present inventive concept, the first and second electrodes 140 and 150 may be transparent electrodes and formed of indium tin oxide (ITO), aluminum zinc oxide (AZO), indium zinc oxide (IZO), ZnO, GZO (ZnO:Ga), In₂O₃, SnO₂, CdO, CdSnO₄, or Ga₂O₃.

The positions and shapes of the first and second electrodes illustrated in FIG. 1 may be an example and may be variously modified. Although not shown, an ohmic-contact layer may be disposed on the second conductivity-type semiconductor layer 126. The ohmic-contact layer may include, for example, p-GaN including a p-type impurity in a high concentration. Alternatively, the ohmic-contact layer may be formed of a metal or a transparent conductive oxide.

FIG. 2 is a flow chart illustrating a method of manufacturing a semiconductor light emitting device according to an example embodiment of the present inventive concept.

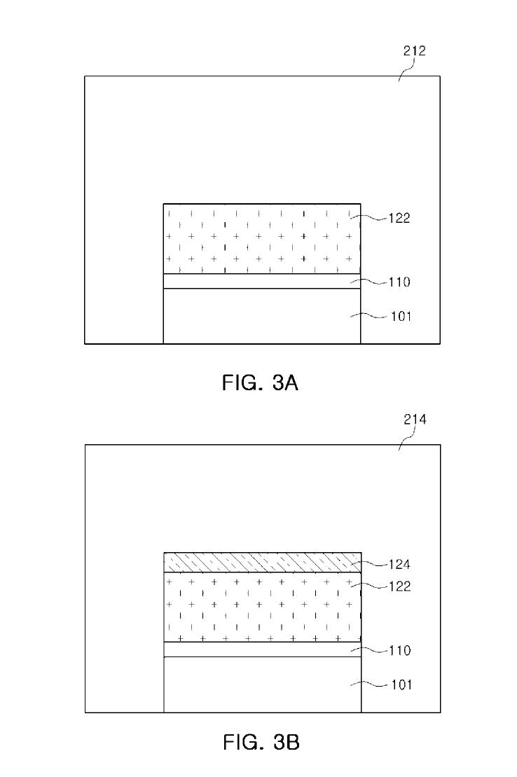

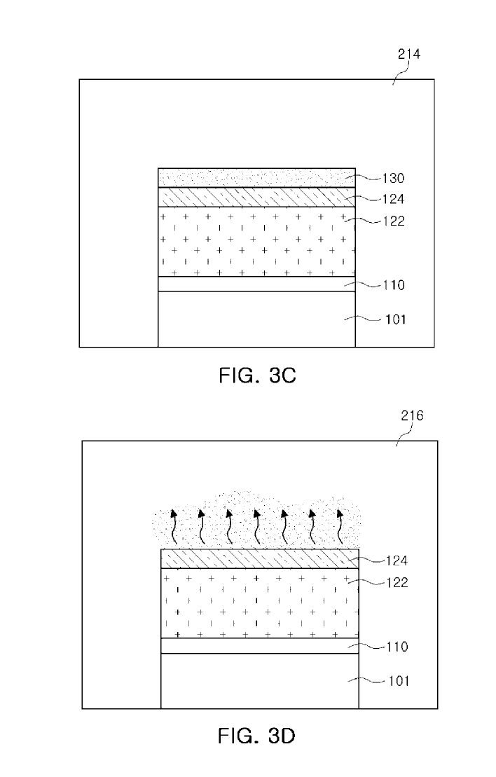

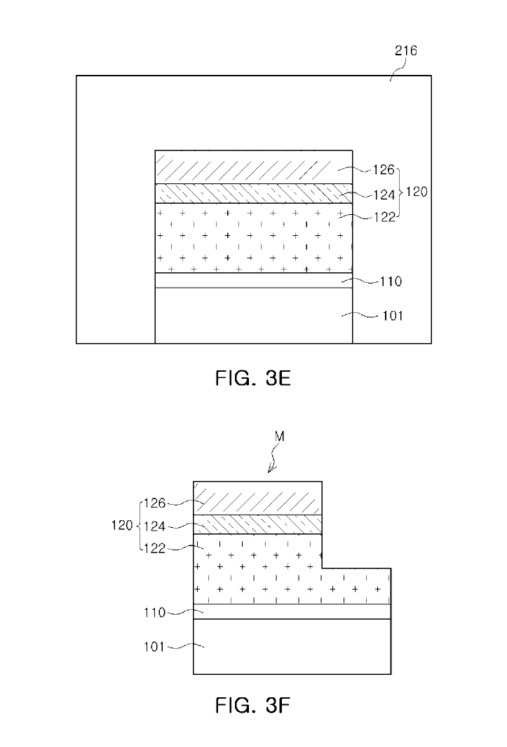

FIGS. 3A through 3F are cross-sectional views schematically illustrating a method of manufacturing a semiconductor light emitting device according to an example embodiment of the present inventive concept.

Referring to FIG. 3A, an operation of forming the buffer layer 110 and the first conductivity-type semiconductor layer 122 of the light emitting structure 120 (refer to FIG. 1) within a first chamber 212 of a process system may be performed.

The first chamber 212, in which a process such as deposition, growth, or the like, is performed, may be maintained in a high vacuum state, relative to atmospheric pressure. The first chamber 212 may be any one of, for example, a metal organic chemical vapor deposition (MOCVD) device, a hydride vapor phase epitaxy (HVPE) device, and a molecular beam epitaxy (MBE) device.

Referring to FIGS. 2 and 3B, first, an operation of transferring the substrate 101 with the first conductivity-type semiconductor layer 122 formed thereon to the second chamber 214, and forming the active layer 124 on the first conductivity-type semiconductor layer may be performed.

During this process, a process temperature of the second chamber 214 may be lower than a process temperature of the first chamber 212. Namely, the first and second chambers 212 and 214 may be operated to use different process temperatures and different types and amounts of source gas. Also, both the first and second chambers 212 and 214 may be MOCVD chambers, or according to an example embodiment of the present inventive concept, the first and second chambers 212 and 214 may respectively be an MOCVD chamber and an HVPE chamber or may be MOCVD chambers having different structures.

When the substrate 101 is transferred from the first chamber 212 to the second chamber 214, the substrate 101 may be exposed in a relatively low vacuum state, and according to an example embodiment of the present inventive concept, the substrate 101 may be exposed to the ambient atmosphere. The transfer may be performed by a robot or a component corresponding thereto.

Accordingly, operation S110 of forming a first region including the first conductivity-type semiconductor layer and the active layer 124 may be performed. In an example embodiment of the present inventive concept, the first region may include the first conductivity-type semiconductor layer 122 and the active layer 124. However, according to an example embodiment of the present inventive concept, the first region may further include the buffer layer 110. The first region may include a defective region including a defect such as dislocation.

According to an example embodiment of the present inventive concept, the first conductivity-type semiconductor layer 122 and the active layer 124 may be formed in the same chamber. In this case, the active layer 124 may be formed at a temperature lower than a temperature of the first conductivity-type semiconductor layer 122.

Referring to FIGS. 2 and 3C, operation S120 of forming a protective layer 130 on the first region of the light emitting structure 120 in the second chamber 214 may be performed.

The protective layer 130 may prevent surface damage or degradation due to temperature or pressure variations based on process temperatures and pressures when the growing process of the light emitting structure 120 is divided and the divided processes are performed in different chambers, and contamination and oxidation due to an impurity introduced when a surface of the semiconductor layer constituting the light emitting structure 120 is exposed in the air or to a relatively low vacuum state while being transferred between chambers. In particular, in an example embodiment of the present inventive concept, the protective layer 130 may be formed on the active layer 124 to enhance characteristics of hole injection from the second conductivity-type semiconductor layer 126 (refer to FIG. 1) to the active layer 124.

The protective layer 130 may be formed of a nitride semiconductor including indium (In) and have a composition of, for example, AlₓIn_{y}Ga_{1-x-y}N (0≦x<1, 0<y≦1) or InₓGa₁₋ₓN (0<x≦1). When the protective layer 130 is formed of a nitride semiconductor including indium (In), it may have qualities of being relatively easily removed under predetermined conditions such as temperature and ambience during a follow-up process. For example, the protective layer 130 formed of a nitride semiconductor including indium (In) may be spontaneously decomposed under a high temperature condition. However, a material of the protective layer 130 is not limited to the nitride semiconductor including indium (In) and may include, for example, any one of InN, ZnO, SiC, MgO, InO, GaO, AlO, SiO, and SiN, and may be doped therein with Ga, Al, In, Si, C, B, Mg, Zn, and the like. A material and a thickness of the protective layer 130 may be selectively applied such that the protective layer 130 is spontaneously removed in a follow-up process.

The protective layer 130 may be formed at a temperature ranging from approximately 450° C. to 800° C., for example. This is because the tendency of the protective layer 130 grown to be thick on a defective region may be varied according to a growth temperature of the protective layer 130. For example, when the protective layer 130 is grown at a relatively high temperature, the protective layer 130 may be preferentially grown on a defective region such as threading dislocation, and here, the protective layer 130 may be grown to become relatively thick to effectively prevent a degradation of the characteristics of the semiconductor light emitting device caused by the defective region.

Referring to FIGS. 2 and 3D, first, operation S130 of transferring the substrate 101 with the first region of the light emitting structure 120 and the protective layer 130 formed thereon from the second chamber 214 to a third chamber 216 may be performed.

When the substrate 101 is transferred from the second chamber 214 to the third chamber 216, the substrate 101 may be exposed to a relatively low vacuum state, and according to an example embodiment of the present inventive concept, the substrate 101 may be exposed to the ambient atmosphere. In this case, contamination of the active layer 124 may be prevented by the protective layer 130.

Thereafter, operation S140 of removing the protective layer 130 may be performed.

When the protective layer 130 is formed of a nitride semiconductor including indium (In), the protective layer 130 has volatility at a temperature of approximately 700° C. or higher, in particular, a temperature of approximately 800° C. or higher, so it may be spontaneously decomposed to be removed. For example, when the protective layer 130 is grown, the protective layer 130 may be grown at a temperature of approximately 800° C. due to pressure of a source gas. However, when an atmosphere of the third chamber 216 is different from an atmosphere of the second chamber 214, the protective layer 130 may have volatility even at a temperature lower than the growth temperature of the protective layer 130.

Also, the protective layer 130 may also be removed under a particular atmosphere, for example, under a hydrogen (H₂) gas atmosphere. The conditions such as a temperature, ambience, or the like, may be adjusted in consideration of a composition, corresponding vapor pressure, and the like, of the protective layer 130, and the protective layer 130 may be removed under a condition of a follow-up process without performing additional process only for removing the protective layer 130. In this case, if necessary, the protective layer 130 may be removed through a separate process.

Referring to FIGS. 2 and 3E, operation S150 of forming a second region on the first region of the light emitting device 120 in the third chamber 216 may be performed. In an example embodiment of the present inventive concept, the second region may include the second conductivity-type semiconductor layer 126. However, in example embodiments of the present inventive concept, the first and second regions may be selectively differentiated in a growth direction from the substrate 101.

The second region may be formed at a temperature higher than a temperature at which the material constituting the protective layer 130 is spontaneously decomposed to be volatilized. Thus, operation S140 of removing the foregoing protective layer 130 may be also performed while the second region is formed. Also, the protective layer 130 may be removed due to an atmosphere of the third chamber 216 for forming the second region.

Referring to FIG. 3F, an operation of etching the light emitting structure 120 may be performed to form a mesa region M such that the first conductivity-type semiconductor layer 122 is partially exposed.

Finally, referring to FIG. 3F together with FIG. 1, the first electrode 140 may be formed on the exposed first conductivity-type semiconductor layer 122 and the second electrode 150 may be formed on the second conductivity-type semiconductor layer 126, thereby manufacturing the semiconductor light emitting device 100.

According to an example embodiment of the present inventive concept, operation S110 of forming the first region, operation S120 of forming the protective layer 130, operation S130 of transferring the substrate to a different chamber, operation S140 of removing the protective layer 130, and operation S150 of forming the second region illustrated in FIG. 2 may be repeatedly performed a plurality of times. Thus, the protective layer 130 may be formed on, for example, at least one of upper surfaces of the first conductivity-type semiconductor layer 122 and the active layer 124 and removed.

FIGS. 4A and 4B are cross-sectional views illustrating a process of the method of manufacturing a semiconductor light emitting device according to an example embodiment of the present inventive concept. Specifically, FIGS. 4A and 4B illustrate an operation corresponding to the operation of forming the protective layer 130 described above with reference to FIG. 3C.

Referring to FIGS. 4A and 4B, first regions 120A and 120B of the light emitting structure 120 (refer to FIG. 1) may include a defective region such as a region in which threading dislocation TD is formed. In the present disclosure, the defective region may refer to a region in which a defect such as threading dislocation TD is exposed or a nearby region thereof. A plurality of threading dislocations may be formed in a direction perpendicular to the substrate 101 and extend to the surfaces of the first regions 120A and 120B. According to an example embodiment of the present inventive concept, the threading dislocations TD may extend from the buffer layer 110.

According to process conditions under which the first regions 120A and 120B are grown, surfaces of the first regions may be flat as the first region 120A illustrated in FIG. 4A or may have pits as the first region 120B illustrated in FIG. 4B. According to an example embodiment of the present inventive concept, the pits P may be formed on purpose through an etching process.

The protective layers 130a and 130b may be grown on the first regions 120A and 120B, respectively, and may have non-uniform thicknesses. For example, in FIG. 4A, the protective layer 130a may have a first thickness T1 above the regions in which the threading dislocation TD is formed, and may have a second thickness T2 smaller than the first thickness T1 in other regions. Accordingly, the protective layer 130a may have protrusions protruding from upper portions of the threading dislocations TD. Also, in FIG. 4B, the protective layer 130b may have a third thickness T3 above the pits P and a fourth thickness T4 smaller than the third thickness T3 in other regions. According to an example embodiment of the present inventive concept, the protective layer 130b may have the third thickness T3 only within the pits P. For example, the first thickness T1 and the third thickness T3 may range from approximately 50 Å to 250 Å, and the second thickness T2 and the fourth thickness T4 may range from approximately 20 Å to 50 Å.

The differences between the thicknesses of the protective layers 130a and 130b may be generated because the regions in which the threading dislocations TD are formed are unstable in terms of energy so precursors of a source gas forming the protective layers 130a and 130b are readily adsorbed thereto to cause nucleation to be performed in those regions. However, thicknesses of the protective layers 130a and 130b are not limited thereto and the protective layers 130a and 130b may be grown to have a uniform thickness above the first regions 120A and 120B.

FIGS. 5A and 5B are cross-sectional views illustrating a process of the method of manufacturing a semiconductor light emitting device according to an example embodiment of the present inventive concept. Specifically, FIGS. 5A and 5B illustrate an operation corresponding to the operation of forming the protective layer 130 described above with reference to FIG. 3C.

Referring to FIGS. 5A and 5B, the first regions 120A and 120B may include a defective region such as a region in which a threading dislocation TD is formed. According to process conditions under which the first regions 120A and 120B are grown, surfaces of the first regions may be flat as the first region 120A illustrated in FIG. 5A or may have pits as the second region 120B illustrated in FIG. 5B. According to an example embodiment of the present inventive concept, the pits P may be formed on purpose through an etching process.

Protective layers 130c and 130d may be formed only on upper surfaces of the regions in which the threading dislocations TD are formed on the first regions 120A and 120B, or may be disposed only within the pits P as illustrated in FIG. 5B. The protective layers 130c and 130d may be grown as a plurality of island regions and spaced apart from one another. However, shapes of the protective layers 130c and 130d are not limited to those illustrated in the drawings and may include a hexagonal prism region, a hexagonal pyramid region, or the like. These shapes may result from instability of the regions in which the threading dislocations TD in terms of energy, and to this end, appropriate process conditions and deposition thicknesses may be selected.

FIG. 6 is a graph illustrating characteristics of a semiconductor light emitting device according to an example embodiment of the present inventive concept.

Referring to FIG. 6, the light output power (indicated by “□” and “ [symbol] ”) and forward voltage characteristics (indicated by “∘” and “•”) of a semiconductor light emitting device (indicated by “ [symbol] ” and “•”) manufactured by a method of manufacturing a semiconductor light emitting device including an operation of forming a protective layer formed of InN and a semiconductor light emitting device (indicated by “□” and “∘”) manufactured by a method of manufacturing a semiconductor light emitting device without an operation of forming a protective layer, over changes in air exposure time duration are illustrated. In FIG. 6, the light output power and forward voltages are illustrated as relative values.

In the present disclosure, a ‘forward voltage’ refers to a voltage, lower than an operating voltage of the semiconductor light emitting device, at which a predetermined forward current flows. Thus, as the forward voltage has a larger value closing to the operating voltage, the semiconductor light emitting device has sharp diode characteristics. The air exposure time duration refers to a time duration in which the substrate 101 on which a portion of the light emitting structure 120 with the protective layer 130 formed thereon as illustrated in FIG. 3C is exposed in the air. Namely, the air exposure time duration refers to a time duration which the substrate 101 is exposed in the air when transferred between the chambers 212 and 214.

It can be seen that, when the protective layer was formed, both the light output power and forward voltage were enhanced. In addition, it can be seen that, without the protective layer, the light output power and forward voltage characteristics were rapidly degraded as the air exposure time duration increases, but with the protective layer, the light output power and forward voltage characteristics were maintained without a significant change.

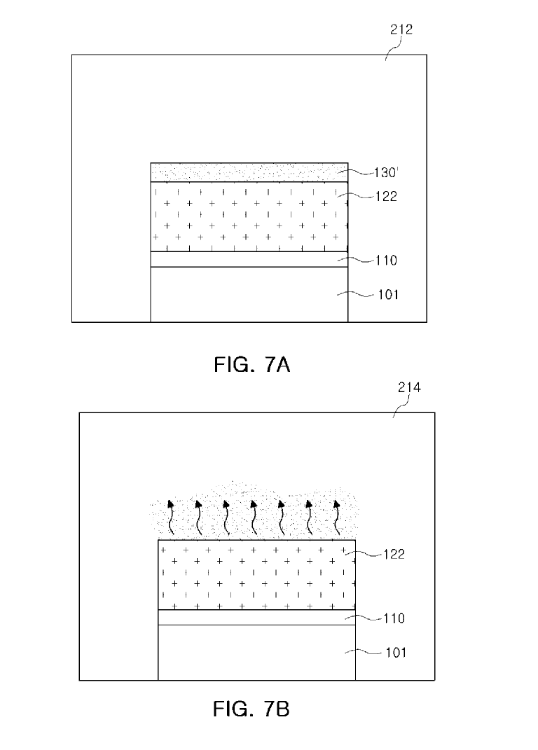

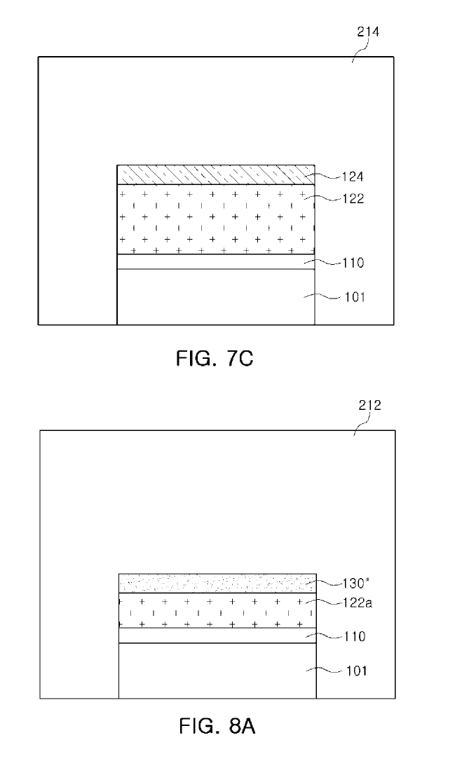

FIGS. 7A through 7C are cross-sectional views schematically illustrating a method of manufacturing a semiconductor light emitting device according to an example embodiment of the present inventive concept.

Referring to FIG. 7A, an operation of forming a first region of the light emitting structure 120 (refer to FIG. 1) on the substrate 101 within the first chamber 212 of the process system may be performed. In an embodiment of the present inventive concept, the first region may include the first conductivity-type semiconductor layer 122. However, according to an example embodiment of the present inventive concept, the first region may further include the buffer layer 110.

Next, an operation of forming a protective layer 130′ on the first region may be performed within the first chamber 212.

Referring to FIG. 7B, first, an operation of transferring the substrate 101 with the first region of the light emitting structure 120 and the protective layer 130′ formed thereon from the first chamber 212 to the second chamber 214 may be performed. When transferred, the substrate 101 may be exposed to a lower vacuum state relative to vacuum states of the chambers 212 and 214 or a lower atmospheric pressure state relative to atmospheric pressure states of the chambers 212 and 214. Even in this case, contamination of the first conductivity-type semiconductor layer 122 may be prevented by the protective layer 130′.

Next, an operation of removing the protective layer 130′ may be performed.

When the protective layer 130′ is formed of a nitride semiconductor including indium (In), the protective layer 130′ may have volatility at a temperature of approximately 700° C. or higher, in particular, at a temperature of approximately 800° C. or higher, so the protective layer 130′ may be spontaneously decomposed to be removed. Also, the protective layer 130′ may be removed under an H₂ gas atmosphere.

Referring to FIG. 7C, an operation of forming the active layer 124 on the first region of the light emitting structure 120 may be performed.

This operation may be sequentially performed with the operation of removing the protective layer 130′ as described above, or may be performed such that at least a partial process time of the operation of forming the active layer 124 overlaps with the process time of the operation of removing the protective layer 130′. For example, the protective layer 130′ may be removed before or while the active layer 124 is deposited, according to process conditions such as a process temperature, a process pressure or a process gas for forming the active layer 124.

Thereafter, the operations as described above with reference to FIGS. 3C through 3F may be performed to manufacture a semiconductor light emitting device. However, according to an example embodiment of the present inventive concept, the operations of forming and removing the protective layer 130 on the active layer 124 described above with reference to FIGS. 3C and 3D may be omitted.

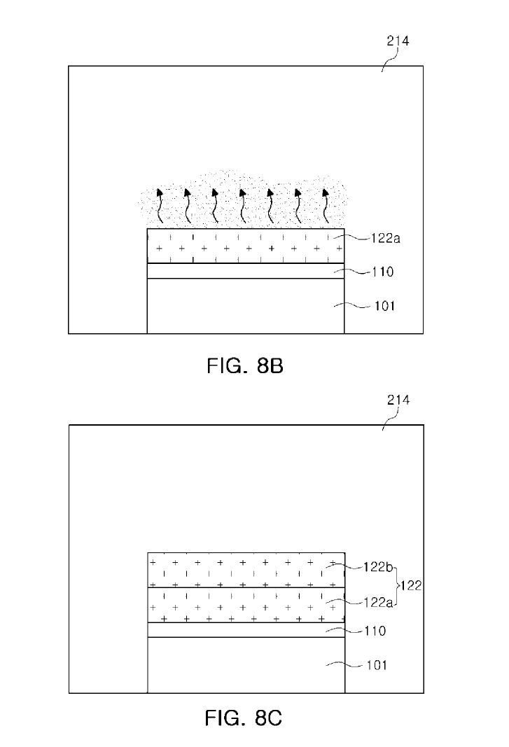

FIGS. 8A through 8C are cross-sectional views schematically illustrating a method of manufacturing a semiconductor light emitting device according to an example embodiment of the present inventive concept.

Referring to FIG. 8A, an operation of forming the first region of the light emitting structure 120 (refer to FIG. 1) on the substrate 101 within the first chamber 212 of the process system may be performed. Referring to FIG. 8A, in an example embodiment of the present inventive concept, the first region may include a first layer 122a, which is a part of the first conductivity-type semiconductor layer 122 (refer to FIG. 1). However, according to an example embodiment of the present inventive concept, the first region may further include the buffer layer 110.

Next, an operation of forming a protective layer 130″ on the first region may be performed within the first chamber 212.

Referring to FIG. 8B, first, an operation of transferring the substrate 101 with the first region of the light emitting structure 120 and the protective layer 130″ formed thereon from the first chamber 212 to the second chamber 214 may be performed. When transferred, the substrate 101 may be exposed to a lower vacuum state relative to vacuum states of the chambers 212 and 214 or a lower atmospheric pressure state relative to atmospheric pressure states of the chambers 212 and 214. Also, in this case, contamination of the first layer 122a of the first conductivity-type semiconductor 122 may be prevented by the protective layer 130″.

Thereafter, an operation of removing the protective layer 130″ may be performed.

When the protective layer 130″ is formed of a nitride semiconductor including indium (In), the protective layer 130″ may have volatility at a temperature of approximately 700° C. or higher, in particular, at a temperature of approximately 800° C. or higher, so the protective layer 130″ may be spontaneously decomposed to be removed. Also, the protective layer 130″ may be removed under an H₂ gas atmosphere.

Referring to FIG. 8C, an operation of forming the second layer 122b of the first conductivity-type semiconductor layer 122 on the first region of the light emitting structure 120 may be performed.

This operation may be sequentially performed with the operation of removing the protective layer 130″ as described above, or may be performed such that at least a partial process time thereof overlaps with the process time of the removing operation. For example, the protective layer 130″ may be removed before or while the second layer 122b is deposited, according to process conditions such as a process temperature, a process pressure or a process gas for forming the second layer 122b.

Thereafter, the operations as described above with reference to FIGS. 3B through 3F may be performed to manufacture a semiconductor light emitting device. However, according to an example embodiment of the present inventive concept, the operations of forming and removing the protective layer 130 on the active layer 124 described above with reference to FIGS. 3C and 3D may be omitted or the operation of forming a protective layer on the first conductivity-type semiconductor layer 122 as described above with reference to FIG. 7B may be further performed.

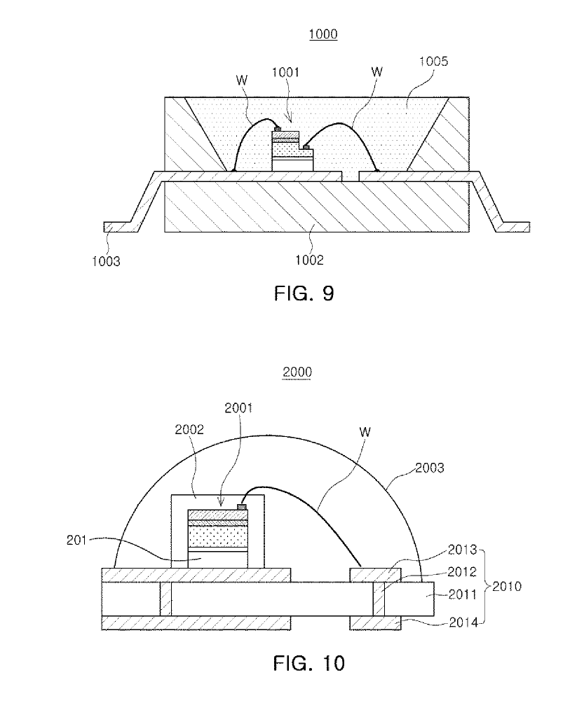

FIGS. 9 and 10 are views illustrating examples of packages employing a semiconductor light emitting device according to an example embodiment of the present inventive concept.

Referring to FIG. 9, a semiconductor light emitting device package 1000 may include a semiconductor light emitting device 1001, a package body 1002, and a pair of lead frames 1003. The semiconductor light emitting device 1001 may be mounted on the lead frame 1003 and electrically connected to the lead frame 1003 through a wire W. According to an example embodiment of the present inventive concept, the semiconductor light emitting device 1001 may be mounted on a different region, for example, on the package body 1002, rather than on the lead frame 1003. The package body 1002 may have a cup shape to improve reflectivity efficiency of light. An encapsulator 1005 formed of a light-transmissive material may be formed in the reflective cup to encapsulate the semiconductor light emitting device 1001, the wire W, and the like. In an example embodiment of the present inventive concept, the semiconductor light emitting device package 1000 may include the semiconductor light emitting device 100 illustrated in FIG. 1, and may be manufactured through at least one of the methods of manufacturing a semiconductor light emitting device illustrated in FIGS. 3A through 3F, 7A through 7C, and 8A through 8C.

Referring to FIG. 10, a semiconductor light emitting device package 2000 may include a semiconductor light emitting device 2001, a mounting board 2010, and an encapsulator 2003. In addition, a wavelength conversion part 2002 may be formed on upper and side surfaces of the semiconductor light emitting device 2001.

The semiconductor light emitting device 2001 may be mounted on the mounting board 2010 and electrically connected to the mounting board 2010 through a wire W and a substrate 201, and in an example embodiment of the present inventive concept, the substrate 201 may be a conductive substrate. In an example embodiment of the present inventive concept, the semiconductor light emitting device 2001 may have a structure identical or similar to that of the semiconductor light emitting device 100 of FIG. 1. In the semiconductor light emitting device 2001, the first electrode 140 in the structure of the semiconductor light emitting device 100 illustrated in FIG. 1 may be replaced with the substrate 201. The semiconductor light emitting device 2001 may be manufactured through at least one of the methods of manufacturing a semiconductor light emitting device illustrated in FIGS. 3A through 3F, 7A through 7C, and 8A through 8C.

The mounting board 2010 may include a board body 2011, an upper electrode 2013, and a lower electrode 2014. Also, the mounting board 2010 may include a through electrode 2012 connecting the upper electrode 2013 and the lower electrode 2014. The mounting board 2010 may be provided as a board such as a printed circuit board (PCB), metal-core printed circuit board (MCPCB), a metal printed circuit board (MPCB), a flexible printed circuit board (FPCB), or the like, and the structure of the mounting board 2010 may be applied to have various forms.

The wavelength conversion part 2002 may include fluorescent materials or quantum dots. The encapsulator 2003 may be formed to have a lens structure with an upper surface having a convex dome shape. However, according to an example embodiment of the present inventive concept, the encapsulator 2003 may have a lens structure having a convex or concave surface to adjust a beam angle of light emitted through an upper surface of the encapsulator 2003.

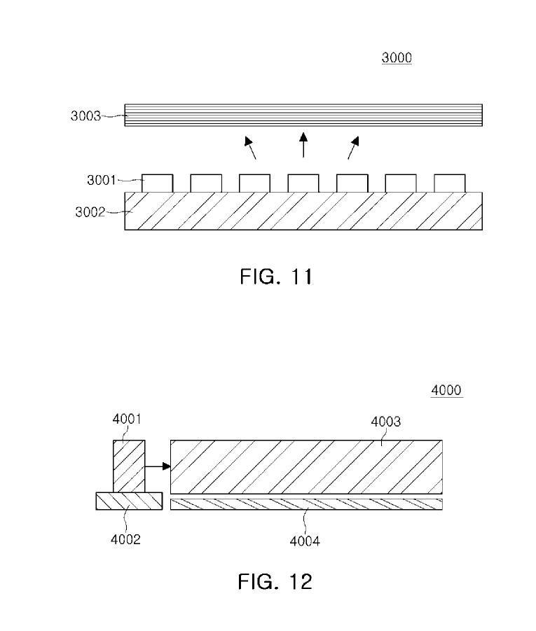

FIGS. 11 and 12 are views illustrating examples of backlights employing a semiconductor light emitting device according to an example embodiment of the present inventive concept.

Referring to FIG. 11, a backlight unit 3000 may include light sources 3001 mounted on a substrate 3002 and one or more optical sheets 3003 disposed above the light sources 3001. In an example embodiment of the present inventive concept, the light sources 3001 may include a semiconductor light emitting device having a structure identical or similar to that of the semiconductor light emitting device 100 of FIG. 1 manufactured through at least one of the methods of manufacturing a semiconductor light emitting device illustrated in FIGS. 3A through 3F, 7A through 7C, and 8A through 8C. The semiconductor light emitting device package having the foregoing structure or a structure similar thereto may be used as the light sources 3001. Alternatively, a semiconductor light emitting device may be directly mounted on the substrate 3002 (a so-called chip-on-board (COB) type) and used.

Unlike the backlight unit 3000 in FIG. 11 in which the light sources 3001 emit light toward an upper side where a liquid crystal display is disposed, a backlight unit 4000 as another example illustrated in FIG. 12 may be configured such that a light source 4001 mounted on a substrate 4002 emits light in a lateral direction, and the emitted light may be made to be incident to a light guide plate 4003 so as to be converted into a surface light source. In an example embodiment of the present inventive concept, the light source 4001 may include a semiconductor light emitting device having a structure identical or similar to that of the semiconductor light emitting device 100 of FIG. 1 manufactured through at least one of the methods of manufacturing a semiconductor light emitting device illustrated in FIGS. 3A through 3F, 7A through 7C, and 8A through 8C. Light, passing through the light guide plate 4003, is emitted upwards, and in order to enhance light extraction efficiency, a reflective layer 4004 may be disposed on a lower surface of the light guide plate 4003.

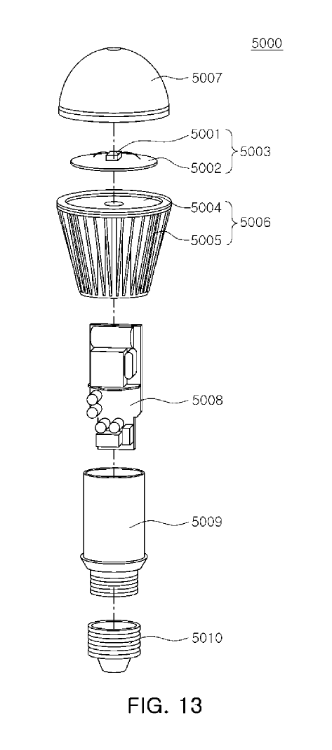

FIG. 13 is a view illustrating an example of a lighting device employing a semiconductor light emitting device according to an example embodiment of the present inventive concept.

Referring to the exploded perspective view of FIG. 13, a lighting device 5000 is illustrated as, for example, a bulb-type lamp and includes a light emitting module 5003, a driving unit 5008, and an external connection unit 5010. Also, the lighting device 5000 may further include external structures such as external and internal housings 5006 and 5009 and a cover unit 5007. In an example embodiment of the present inventive concept, the light emitting module 5003 may include a semiconductor light emitting device 5001 having a structure identical or similar to that of the semiconductor light emitting device 100 of FIG. 1 manufactured through at least one of the methods of manufacturing a semiconductor light emitting device illustrated in FIGS. 3A through 3F, 7A through 7C, and 8A through 8C, and a circuit board 5002 having the semiconductor light emitting device 5001 mounted thereon. In an example embodiment of the present inventive concept, it is illustrated that a single semiconductor light emitting device 5001 is mounted on the circuit board 5002, but a plurality of semiconductor light emitting devices may be installed as needed. Also, the semiconductor light emitting device 5001 may be manufactured as a package and subsequently mounted, rather than being directly mounted on the circuit board 5002.

The external housing 5006 may serve as a heat dissipation unit and may include a heat dissipation plate 5004 disposed to be in direct contact with the light emitting module 5003 to enhance heat dissipation and heat dissipation fins 5005 surrounding the lateral surfaces of the lighting device 5000. Also, the cover unit 5007 may be installed on the light emitting module 5003 and have a convex lens shape. The driving unit 5008 may be installed in the internal housing 5009 and connected to the external connection unit 5010 having a socket structure to receive power from an external power source. Also, the driving unit 5008 may serve to convert power into an appropriate current source for driving the semiconductor light emitting device 5001 of the light emitting module 5003, and provide the same. For example, the driving unit 5008 may be configured as an AC-DC converter, a rectifying circuit component, or the like.

Also, although not shown, the lighting device 5000 may further include a communications module.

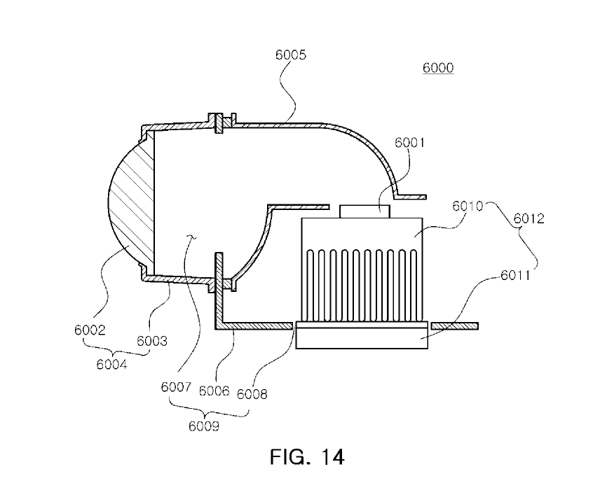

FIG. 14 is a view illustrating an example of a headlamp employing a semiconductor light emitting device according to an example embodiment of the present inventive concept.

Referring to FIG. 14, a headlamp 6000 used as a vehicle lamp, or the like, may include a light source 6001, a reflective unit 6005, and a lens cover unit 6004. The lens cover unit 6004 may include a hollow guide 6003 and a lens 6002. The light source 6001 may include at least one of semiconductor light emitting device packages of FIGS. 9 and 10. The headlamp 6000 may further include a heat dissipation unit 6012 outwardly dissipating heat generated by the light source 6001. In order to effectively dissipate heat, the heat dissipation unit 6012 may include a heat sink 6010 and a cooling fan 6011. Also, the headlamp 6000 may further include a housing 6009 fixedly supporting the heat dissipation unit 6012 and the reflective unit 6005, and the housing 6009 may have a body unit 6006 and a central hole 6008 formed in one surface thereof, in which the heat dissipation unit 6012 is coupled. Also, the housing 6009 may have a front hole 6007 formed in the other surface integrally connected to the one surface and bent in a right angle direction. The reflective unit 6005 is fixed to the housing 6009 such that light generated by the light source 6001 is reflected thereby to pass through the front hole 6007 to be output outwardly.

As set forth above, according to example embodiments of the present inventive concept, by growing a light emitting structure within a plurality of chambers, a method of manufacturing a semiconductor light emitting device and a method of manufacturing a semiconductor light emitting device package having enhanced luminous efficiency and productivity may be provided.

Advantages and effects of the present disclosure are not limited to the foregoing content and any other technical effects not mentioned herein may be easily understood by a person skilled in the art from the foregoing description.

While example embodiments have been shown and described above, it will be apparent to those skilled in the art that modifications and variations could be made without departing from the spirit and scope of the present disclosure as defined by the appended claims.

What is claimed is:

1. A method of manufacturing a semiconductor light emitting device, the method comprising:
forming, on a substrate, a first region of a light emitting structure, the light emitting structure including a first conductivity-type semiconductor layer, an active layer, and a second conductivity-type semiconductor layer;
forming a protective layer on the first region in a first chamber;
transferring the substrate with the first region and the protective layer formed thereon to a second chamber; and
forming a second region on the first region, wherein:
the first and second regions are disposed in a direction perpendicular to the substrate, and
the protective layer is grown above a defective region included in the first region and removed before or while the second region is formed.

2. The method of claim 1, wherein the protective layer has a first thickness on the defective region and has a second thickness lower than the first thickness on a region other than the defective region.

3. The method of claim 2, wherein the protective layer has a protrusion protruding from the defective region.

4. The method of claim 1, wherein the defective region is a region in which a threading dislocation is formed.

5. The method of claim 1, wherein the first region has a pit formed in an upper surface of the defective region.

6. The method of claim 5, wherein the protective region is disposed within the pit.

7. The method of claim 1, wherein the protective layer includes a plurality of island regions disposed above the defective region.

8. The method of claim 1, wherein the protective layer has a composition of AlₓIn_{y}Ga_{1-x-y}N (0≦x<1, 0<y≦1).

9. The method of claim 8, wherein the protective layer is formed of InN.

10. The method of claim 1, wherein the protective layer is formed of a material having volatility at a temperature of approximately 700° C. or higher.

11. The method of claim 1, wherein the protective layer is formed at a temperature ranging from approximately 450° C. to 800° C.

12. The method of claim 1, wherein the second region is formed at a temperature above a temperature at which a material constituting the protective layer is decomposed to be volatilized.

13. The method of claim 1, wherein the forming of the second region comprises injecting a hydrogen (H₂) gas.

14. The method of claim 1, wherein:
the first region comprises the first conductivity-type semiconductor layer and the active layer, and
the second region comprises the second conductivity-type semiconductor layer.

15. The method of claim 14, wherein the forming of the first region comprises:
forming the first conductivity-type semiconductor layer on the substrate within the first chamber; and
forming the active layer and the protective layer on the first conductivity-type semiconductor layer within the second chamber,
wherein the forming of the second region comprises forming the second conductivity-type semiconductor layer on the active layer within a third chamber.

16. The method of claim 1, wherein the first conductivity-type semiconductor layer, the active layer, and the second conductivity-type semiconductor layer are formed within respective chambers that are different from one another.

17. A method of manufacturing a semiconductor light emitting device, the method comprising:
forming, on a substrate, a part of a light emitting structure as a first region, the light emitting structure including a plurality of semiconductor layers and the first region including a defective region;
forming a protective layer covering an upper portion of the defective region on the first region; and
forming, on the first region, at least a part of the remaining region of the light emitting structure as a second region.

18. The method of claim 17, wherein the protective layer has a first thickness on the defective region and has a second thickness lower than the first thickness on a region other than the defective region.

19. The method of claim 17, wherein the protective layer is formed only on the defective region.

20. A method of manufacturing a semiconductor light emitting device package, the method comprising:
growing a first conductivity-type semiconductor layer, an active layer, and a second conductivity-type semiconductor layer on a substrate to form a light emitting structure;
removing at least a portion of the light emitting structure to form a first electrode electrically connected to the first conductivity-type semiconductor layer;
forming a second electrode electrically connected to the second conductivity-type semiconductor layer; and
mounting the light emitting structure on a package board,
wherein the forming of the light emitting structure comprises:
forming a part of a light emitting structure as a first region including a plurality of semiconductor layers, and including a defective region;
forming a protective layer covering an upper portion of the defective region on the first region; and
forming at least a part of the remaining region of the light emitting structure as a second region on the first region.
